(19) United States
(12) Patent Application Publication
(10) Pub. No.: US 2006/0278997 A1
(43) Pub. Date: Dec. 14, 2006

(54) Soldered assemblies and methods of making the same

(75) Inventors: David Gibson, Lake Oswego, OR (US); Giles Humpston, Aylesbury (GB); Belgacem Haba, Saratoga, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/284,289

(22) Filed: Nov. 21, 2005

Related U.S. Application Data
(60) Provisional application No. 60/632,241, filed on Dec. 1, 2004.

(51) Int. Cl. H01L 23/48

(52) U.S. Cl. 257/778

(57) ABSTRACT

A microelectronic element is mounted to a substrate using solder elements disposed at least partially within vias of the substrate. The vias have tapering walls. During reflow of the solder, the microelectronic element may move toward the substrate. Such movement may be impelled, for example, by interfacial tension between the solder and the tapering via wall. This movement reduces the height of the completed assembly.

### CROSS-REFERENCE TO RELATED APPLICATIONS

The present application claims the benefit of the filing date of U.S. Provisional Patent Application No. 60/632,241, filed Dec. 1, 2005, the disclosure of which is incorporated herein by reference.

### BACKGROUND OF THE INVENTION

The present invention relates to microelectronic assemblies and to methods of making such assemblies.

Microelectronic elements such as semiconductor chips commonly are formed as thin, flat bodies having contacts exposed at the front surface of the body, the contacts being electrically connected to the electronic components within the body. Other structures, such as those incorporating passive electronic devices, commonly referred to as “integrated-passives-on-chip” or “IPOCS,” have a similar configuration. To use the chip or other microelectronic element, the contacts are electrically connected to structures of a larger circuit. In a technique referred to as “flip-chip” mounting, the microelectronic element is used in a “bare” or unpackaged condition. The bare element is placed onto a circuit board or other circuit panel with the front face facing downwardly toward the circuit panel and the contacts of the microelectronic element are solder-bonded to contact pads on the circuit panel. Flip-chip mounting conserves area on the circuit panel. However, flip-chip mounting requires specialized assembly techniques to avoid damage to the microelectronic element. Moreover, the circuit boards for use with flip-chip mounting must provide for signal routing to all of the various contact pads which will be bonded to the contacts of the chip. Where the contacts of the chip are provided in a densely spaced array, the contact pads of the circuit board similarly must be positioned in a dense array. There is little space available between the contact pads for routing signal lines to those contact pads in the interior of the array. Although this problem can be overcome by adding routing layers below the surface of the panel, this approach adds complexity and cost to the circuit panel. This problem is particularly severe where the contacts of the chip, and hence the contact pads of the circuit panel, must be placed in an array with a “pitch” or distance between adjacent pads of about 200 microns or less.

In other techniques, the microelectronic element is provided in a package which protects the element itself from physical or chemical damage, and which facilitates connection of the element to a circuit panel. Packages intended for surface-mounting to a circuit panel typically include a package substrate which overlies the front or rear surface of the microelectronic element body. The package substrate has an inner surface facing toward the microelectronic element body and an outer surface facing away from the body, and has terminals exposed at the outer surface. The terminals are electrically connected to the contacts of the chip by a wide variety of techniques, including wire-bonding, lead-bonding and flip-chip mounting of the chip to the substrate. The package typically also includes a cover or encapsulant at least partially surrounding the microelectronic element body. Typically, the terminals are disposed in a pattern with sufficient distance between terminals to facilitate solder-bonding of the terminals to the contact pads on a circuit panel using standard surface-mounting techniques. Also, the terminals on the packaged substrate can be placed in an arrangement which minimizes the routing problem mentioned above. The substrate itself can incorporate traces which redistribute the signal routing from the pattern formed by the terminals to the pattern of the contact pads on the chip.

It is highly desirable to make chip packages as compact as possible. Packages referred to as “chip-scale packages” occupy an area of the circuit panel about 1.5 times the area of the front or rear surface of the chip itself or less. Also, it is desirable to reduce the height of the package, i.e., the dimension of the package which will be transverse to the plane of the circuit panel and typically transverse to the planes of the front and back surfaces of the chip itself.

Despite considerable effort devoted to development of chip packages heretofore, further improvement would be desirable.

### SUMMARY OF THE INVENTION

One aspect of the present invention provides microelectronic assemblies. A microelectronic assembly in accordance with this aspect of the invention desirably includes a first microelectronic element having a front face with contacts thereon and also includes a substrate. The substrate desirably has oppositely-directed top and bottom faces and has top vias extending downwardly into the substrate from the top face. The top vias have metallic circumferential top via walls and are tapered so that the diameters of the top vias decrease progressively in the downward direction, away from the top surface. The substrate desirably also has electrically conductive traces thereon, at least some of the traces being electrically connected to at least some of the top via walls. The assembly according to this aspect of the invention desirably also includes solder elements disposed at least partially within the top vias, the solder elements being bonded to the contacts of the first microelectronic elements and to the top via walls.

A further aspect of the invention provides methods of making microelectronic assemblies. A method according to this aspect of the invention desirably includes the step of juxtaposing a first microelectronic element with a substrate, so that a front surface of the first microelectronic element confronts the top surface of the substrate, and so that solder elements partially received in top vias of the substrate are engaged with contacts exposed at the front surface of the microelectronic elements and with metallic circumferential walls of the top vias. The vias desirably are tapered so that the circumferential wall of each via slopes inwardly towards a central axis in the downward direction, away from the top surface. The method desirably also includes reflowing the solder elements and solidifying the solder elements.

The method may further include moving the first microelectronic elements toward the substrate during the reflowing step. Such movement may be at least partially impelled by interfacial tension of molten solder with the metallic circumferential walls of the vias during the reflowing step.

### BRIEF DESCRIPTION OF THE DRAWINGS

FIG. 1 is a diagrammatic sectional view depicting components used in a method according to one embodiment of the invention.

FIG. 2 is a diagrammatic sectional view depicting the components of FIG. 1 at a later stage in the method.

FIG. 3 is a diagrammatic sectional view depicting the assembly made according to the method of FIGS. 1 and 2.

FIG. 4 is a fragmentary, diagrammatic top plan view depicting a component used in the method of FIGS. 1-3.

FIG. 5 is a diagrammatic sectional view depicting an assembly in accordance with a further embodiment of the invention.

FIG. 6 is a diagrammatic sectional view depicting an assembly in accordance with a still further embodiment of the invention.

FIG. 7 is a diagrammatic sectional elevational view depicting an assembly in accordance with yet another embodiment of the invention.

FIG. 8 is a diagrammatic sectional view depicting an assembly in accordance with a still further embodiment of the invention.

FIG. 9 is a diagrammatic sectional view depicting an assembly according to yet another embodiment of the invention.

### DETAILED DESCRIPTION

An assembly in accordance with one embodiment of the invention uses a substrate 20 having a top surface 22 and bottom surface 24. The substrate has top vias 26 extending downwardly from top surface 22. In the particular embodiment depicted, the vias 26 extend entirely through the substrate to bottom surface 24. Each via thus defines a top opening 27 at top surface 22, a bottom opening 29 at the bottom surface and a vertical axis 28 transverse to the top and bottom surfaces. Each via is bounded by a circumferential wall 30 extending around the vertical axis. The circumferential walls of the vias have exposed surfaces formed from one or more metals wettable by molten solder. Substrate 20 most preferably electrically isolates the circumferential walls 30 of the various vias 26 from one another, except where electrical connections are deliberately formed between particular vias as discussed further below. Substrate 20 may be a solid body of a dielectric material or may be a metallic or other conductive body having dielectric layers (not shown) surrounding the circumferential walls of the various vias. Most preferably, substrate 20 is formed from a glass, glass-ceramic, ceramic or semiconducting material. Substrate 20 desirably has a coefficient of thermal expansion (“CTE”) matched or nearly matched to the CTE of the chip to be assembled with the substrate. Where the chip is formed primarily of silicon, the CTE of the chip typically is about 1.5 to 4.5×10⁻⁶/° C., and the CTE of the substrate 20 desirably is about 0 to about 6×10⁻⁶/° C., more preferably about 1.5 to about 4.5×10⁻⁶/° C.

The vias 26 are tapered such that the internal diameter D of each via decreases progressively in the downward direction, away from top surface 22 and toward bottom surface 24. Stated another way, the surface defined by circumferential wall 30 converges toward the axis 28 in the downward direction, so that portions of the circumferential wall on opposite sides of the axis slope toward one another in the downward direction. Most typically, the interior surface of each via defined by circumferential wall 30 is in the form of a frustum of a cone or other surface of revolution about axis 28. However, the interiors of the vias may have other shapes. For example, the interior of each via may be in the form of a pyramid or a frustum of a pyramid. For a via which is not in the form of a body of revolution about axis 28, the diameter of the via can be taken as the average dimension transverse to the axis 28 of the via. The included angle a defined by the convergent via wall desirably is about 5°-75°, more preferably about 15°-60° and most preferably about 20°. The tapered vias can be formed by etching substrate 20 from top surface 22 and depositing a metal by processes such as sputtering, vapor deposition and chemical vapor deposition to form the circumferential wall 30. Borosilicate glass tends to form vias having walls with an included angle of about 20° when etched with the an acid solution incorporating fine abrasive particles, which is directed as a jet towards top surface 22. A temporary protective film (not shown) having apertures at those sites where through holes are required may be applied prior to etching and removed after etching. Also, the substrate, with the tapered vias, may be fabricated by processes such as those disclosed in co-pending, commonly assigned U.S. patent application Ser. No. 10/949,674, filed Sep. 24, 2004; Ser. No. 10/928,839, filed Aug. 27, 2004; Ser. No. 10/949,844, filed Sep. 24, 2004; Ser. No. 10/948,976, filed Sep. 24, 2004; Ser. No. 10/949,575, filed Sep. 24, 2004; Ser. No. 10/949,847, filed Sep. 24, 2004; and Ser. No. 10/949,693, filed Sep. 24, 2004, the disclosures of which are hereby incorporated by reference herein.

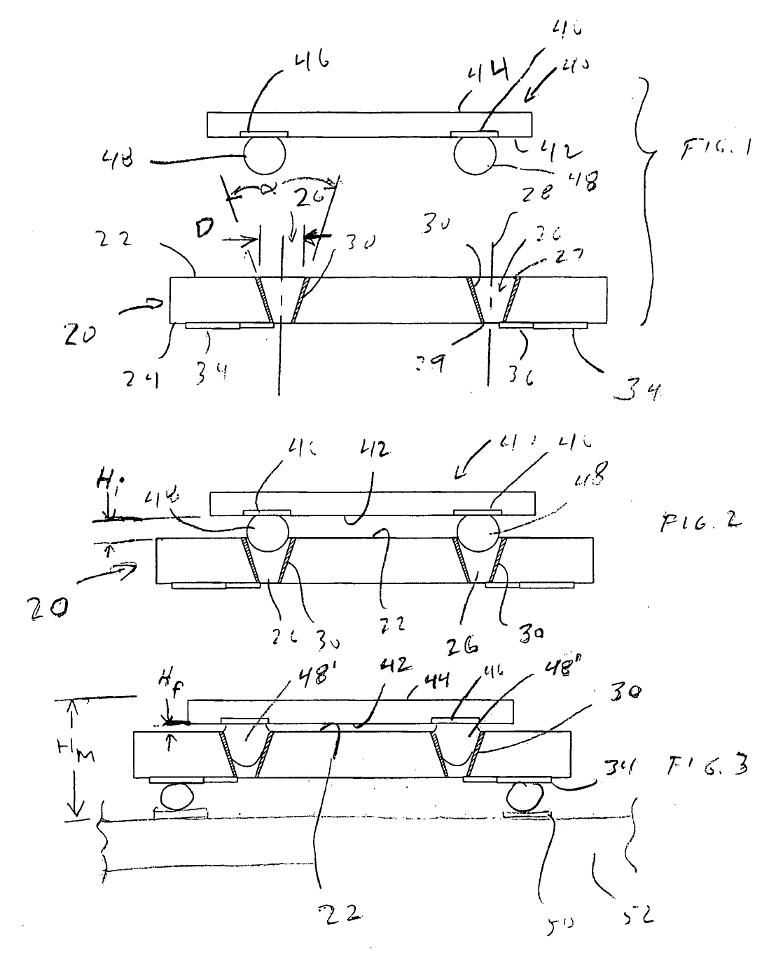

In this embodiment, substrate 20 has electrically conductive terminals 34 exposed at bottom surface 24. As used in this disclosure, a statement that an electrically conductive structure is “exposed at” a surface of a dielectric structure indicates that the electrically conductive structure is available for contact with a theoretical point moving in a direction perpendicular to the surface of the dielectric structure toward the surface of the dielectric structure from outside the dielectric structure. Thus, a terminal or other conductive structure which is exposed at a surface of a dielectric structure may project from such surface; may be flush with such surface; or may be recessed relative to such surface and exposed through a hole or depression in the dielectric. At least some of the terminals 34 are electrically connected to at least some of the via circumferential walls 30 as, for example, by electrically conductive traces 36 carried by substrate 20. In this embodiment, traces 36 are disposed on the bottom surface 24. In other embodiments, however, the traces may be disposed within the interior of the dielectric, on top surface 22 or both. The traces and terminals may be formed from the same metal as the via walls, or from a different metal. Although only two terminals 34 are depicted in FIG. 1, it should be appreciated that a typical substrate will have many terminals as dictated by circuit requirements. These terminals are distributed in a pattern suitable for surface-mounting to a circuit panel. For example, terminals 34 may be distributed in an “area array,” in which terminals 34 are substantially equally spaced over the entire bottom surface 24, or over a portion of such surface. Alternatively, terminals 34 may be disposed in rows near the edges of substrate 20. Most commonly, terminals 34 are disposed at a terminal-to-terminal spacing or “pitch” greater than the pitch of the vias 26.

The method according to this embodiment of the invention also uses a first microelectronic element, in this case a chip 40, having a front surface 42, a rear surface 44 and contacts 46 exposed at front surface 42. Solder elements 48, which, in this embodiment, are substantially spherical solid solder balls, are applied to the contacts 46 of the chip using conventional solder ball application techniques so as to leave the solder elements 48 projecting from the front surface 42 of the chip.

Chip 40 is juxtaposed with substrate 20 with the front face 42 of the chip facing downwardly toward the top surface 22 of the substrate. The solder elements 48 are aligned with vias 26 and engaged therein so that, at this stage of the process, the solder elements are at least partially received in the vias, and at least some of the solder elements are in contact with the circumferential walls of at least some the vias, as well as with the contacts 46 of the chip. Conventional machine-vision systems can be used to align the contacts 46 and solder elements 48 of the chip with vias 30. Use of a substrate 20 formed from a transparent material such as glass facilitates the alignment process. It is not essential for all of solder elements 48 to be fully seated within vias 26 at this stage of the process, or even for all of the solder balls to be in contact with all of the circumferential via walls 30. Minor differences in the vertical dimensions of the solder elements, and minor deviations of the solder elements 48 and chip contacts 46 from perfect coplanarity with one another, will not adversely affect the process.

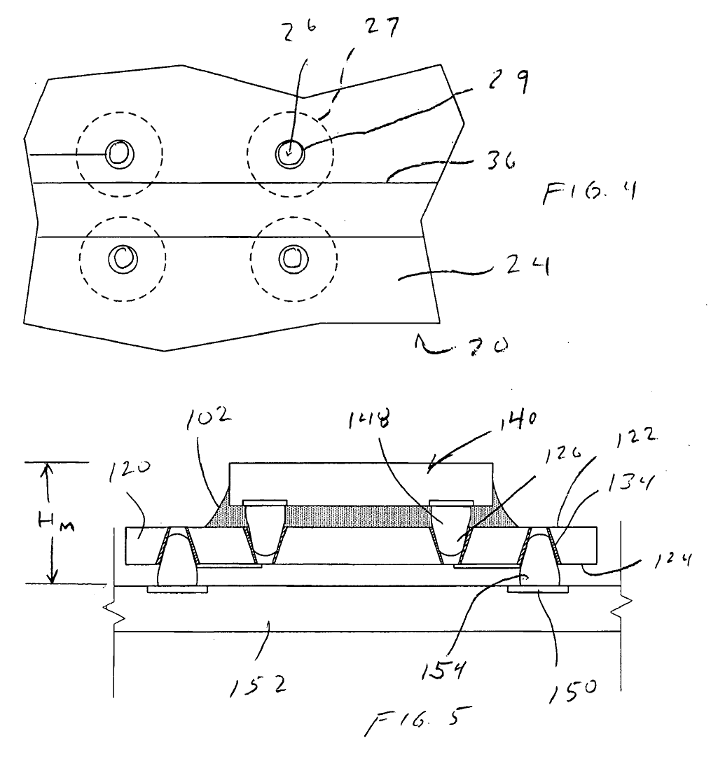

In the next stage of the process, solder elements 48 are liquefied or reflowed, typically by heating the entire assembly in a conventional or reflow oven. During this process, the solder in elements 48 flows into contact with the circumferential walls 30 of the vias under the influence of interfacial tension between the liquid solder and the circumferential walls, thus forming modified solder elements 48′ (FIG. 3). As the solder flows to fill the vias, the chip 40 moves downwardly toward substrate 20. Thus, the height H_{F} of the front surface 42 on the chip above the top surface 22 of the substrate after reflow is less than the corresponding initial dimension H_{I} (FIG. 2) before reflow. Stated another way, the solder flow caused by interfacial tension moves the chip downwardly toward the substrate. After the reflow operation, the assembly is cooled, leaving the solder elements 48′ in their modified shape bonded to the circumferential walls of the vias. This modified shape is indicated only schematically in FIG. 3. In practice, the actual shape of each solder element will depend on the shapes of the vias, the surface tension of the solder and the propensity of the molten solder to wet the vias. Desirably, the spacing or height H_{F} of the chip front surface 42 above substrate top surface 22 after reflow is less than the diameters of the via top openings 27, and more preferably less than one-half the diameters of the via top openings. The final height H_{F} may be 0. Stated another way, the reflow process may continue until the front surface 42 of the chip abuts the top surface 22 of the substrate. Conventional fluxes (not shown) may be applied to the solder elements, to the vias or both prior to engaging the chip and substrate. These fluxes may be removed by washing the assembly after the reflow process. Preferably, however, the process is performed without application of flux as, for example, by heating the assembly under vacuum to perform the reflow operation.

In the finished condition, after reflow and cooling, the contacts 46 of the chip are connected to the terminals 34 on the substrate. The resulting assembly provides a low-height chip package. As seen in FIG. 3, the package can be assembled to a circuit panel as by bonding terminals 34 to contact pads 50 on circuit panel 52 using conventional surface-mounting techniques.

Only a few vias 26 are depicted in FIGS. 1-3. In actual practice, numerous vias typically are provided on the substrate. As shown in FIG. 4, the via configuration provides significant advantageous in routing traces, particularly along bottom surface 24 (the surface facing the viewer in FIG. 4). The top opening 27 of each via is significantly larger than the bottom opening 29 of the via at the bottom surface 24. Therefore, the bottom opening 29 of each via occupies only a very small region of the bottom surface. As seen in the FIG. 4, traces 36 can run in the area of bottom surface 20 disposed under the top openings 27 of the vias. This facilitates routing of the traces, even where the vias are closely spaced, at a patch of 200 microns or less.

The traces 36 optionally may include traces interconnecting certain vias with one another. Such an arrangement can be used, for example, where signals from one contact 46 of the chip are carried to another contact on the same chip. In this arrangement, the traces on the substrate take the place of traces within the chip itself, thus, simplifying design of the chip. Moreover, the traces on the substrate can be substantially larger in cross-sectional area than traces within the chip itself, and can be formed from a highly conductive metal such as copper. Therefore, such traces can provide a low-impedance conductive path for rapid signal propagation between widely separated portions of the chip. The substrate optionally may be provided with features such as conductive ground planes to provide controlled-impedance connections. Traces 36 on the substrate also may interconnect two or more terminals 34 with one another. In this arrangement, the traces on the substrate take the place of traces on the circuit panel.

The assembly as discussed above with reference to FIGS. 1-4 provides a very compact, low-height unit. Placement of the solder elements 48′ (FIG. 3) partially or wholly within the vias 26 reduces the overall height of the package, and hence, reduces the mounted height H_{M} of the package above the circuit board when the package is mounted to a circuit board. The unit may include other elements such as an overmolding (not shown) or casing covering the top surface of the substrate and the rear surface 44 of the chip. Preferably, however, such overmolding does not add appreciably to the height of the unit. Most preferably, the area of the substrate (the area of the bottom surface 24) is no more than about 1.5 times the area of the chip (the area of front surface 42), so that the unit provides a chip scale package.

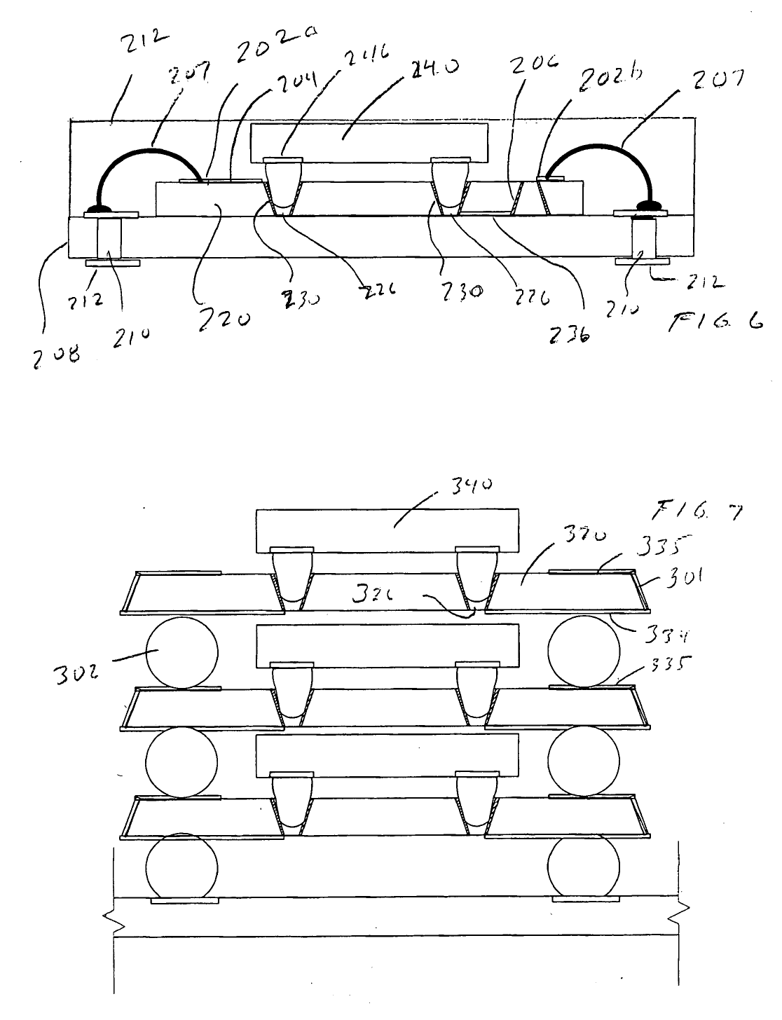

As seen in FIG. 5, a unit according to a further embodiment of the invention incorporates a substrate 120, chip 140, solder masses 148 and vias 126 similar to those discussed above with reference to FIGS. 1-4. In this unit, however, the terminals 134 are formed as bottom vias which extend into the substrates 120 from the bottom surface 124, and which taper in the upward direction, toward top surface 122. Stated another way, the bottom vias forming terminals 134 have the opposite taper from top vias 126. Vias 134 and 126 have metallic circumferential walls similar to those discussed above with reference to FIGS. 1-4. The circumferential walls of vias 134 are connected to the circumferential walls of vias 126. In this embodiment, the package can be mounted to contact pads 150 on a circuit board 152 using solder elements 154 which are partially received-in the bottom vias 134. Thus, the process for mounting the package to circuit panel 152 is similar to the process used to mount the chip 140 to the substrate. Stated another way, in this embodiment, circuit panel 152 constitutes a further microelectronic element mounted to the substrate 120 using a process as discussed above. The solder elements, typically in spherical form, are provided in engagement with the contact pads 150 and the circumferential walls of the bottom vias 134 and flow into the condition depicted in FIG. 5 when the solder elements are reflowed. In the embodiment of FIG. 5, chip 140 and substrate 120 are provided as a unit forming a packaged chip, together with an encapsulant 102, which protects the front surface of the chip and at least a portion of the top surface of the substrate. This unit is provided in finished form to the circuit panel assembler and, in turn, assembled to circuit panel 152. Thus, solder elements 154 are reflowed after solder elements 148. Solder elements 154 may have a lower melting temperature than solder elements 148. The use of tapered vias to house both solder elements 148 and solder elements 154 further reduces the mounted height H_{M} of the assembly. Thus, only a small portion of solder elements 154 need protrude from vias 134. In a further variant, vias 126 may be omitted, and chip 140 may be mounted to substrate 120 and connected to the walls of vias 134 by conventional techniques. In such an embodiment, surface 124 would be considered the “top” surface.

A package according to a further embodiment of the invention (FIG. 6) includes a substrate 220 and first microelectronic element or chip 240 mounted to the substrate. These elements are similar to the corresponding elements of the embodiments discussed above. In this embodiment, however, substrate 220 does not have terminals exposed on its bottom surface. Instead, substrate 220 has bond pads 202A and 202B exposed at its top surface. Bond pad 202A is connected to the circumferential wall 230 of a top via 226 by traces 204 extending along the top surface of the substrate, whereas bond pad 202B is connected to the circumferential wall 230 of another top via 226 by a trace 236 extending along the bottom surface of the substrate, and a further via 206 connecting trace 236 with bond pad 202B. The two different connections are shown in FIG. 6 merely for purposes of illustration. Typically, each unit would include only one type of connection. Also, other types of connections between the circumferential walls of the top vias and the bond pads may be employed as, for example, traces extending within the body of substrate 220.

Substrate 220, in turn, is positioned on an additional substrate 208. The bond pads 202A and 202B are connected by wire bonds 207 to metallic terminal structures 210 extending through the additional substrate 208 so as to form terminals 212 exposed at the bottom or outer surface of this additional substrate. An overmolding 212 covers the wire bonds 207 and the substrate 220, as well as chip 240. In this embodiment, substrate 220 serves as a rerouting element which reroutes the connections from the contacts 246 of the chip to the bond pads 202A, 202B. Such an arrangement can be used, for example, where the contacts 246 of the chip itself are in a pattern unsuitable for wire-bonding. A package of this type may incorporate features such as one or more layers of a compliant material, or other features adopted to permit movement of terminals 212 on the additional substrate relative to substrate 220, and hence relative to chip 240. Such relative movability minimizes stress on the solder joints (not shown) used to connect terminals 212 to a circuit panel.

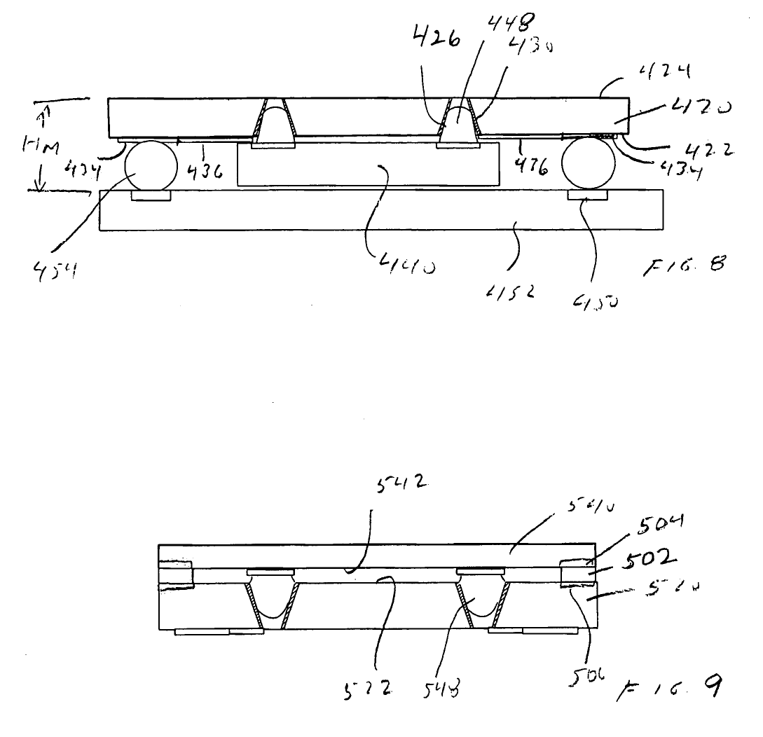

An assembly according to yet another embodiment of the invention includes a substrate 320 having top vias 326 similar to the vias discussed above with reference to FIGS. 1-3. The substrate 320 has terminals 334 exposed at the bottom surface of the substrate and has terminals 335 exposed at the top surface of the substrate. At least some of the top terminals 335 are connected to at least some of the bottom terminals 334. Also, at least some of the terminals are connected to the circumferential walls 330 of at least some of the vias 326. Although terminals 335 and 334 are depicted as separate structures connected by traces 301 extending along the edges of the substrate 320, any other form of terminal can be employed. For example, a single metallic structure can form both terminals 334 and 335. In one embodiment, a planar terminal disposed on the bottom surface may be exposed at the top surface of the substrate by a hole (not shown) extending through the substrate in alignment with the terminals, so that the same terminal constitutes both a bottom terminal and a top terminal. Assemblies of this type can be stacked on one another so as to form a larger assembly. The bottom terminals 334 on each unit (other than the lowest unit in the stack) are connected to the top terminal 335 of the next lower unit in the stack. In the particular embodiment shown in FIG. 7, this connection by made by relatively large conductive elements such as solder balls 302. Other types of conductive elements can be employed as, for example, elongated pins projecting from the top terminals, the bottom terminals or both; elongated solder masses; and the like. The ability to mount the chip 340 or other microelectronic element close to substrate 320, provided by the via structure as discussed above, is particularly valuable in the case of a stacked assembly. By reducing the height of each unit in the stack, the overall stack height is minimized. Also, the required height of conductive elements 302 is minimized. This allows the use of relatively small solder balls as the conductive elements, which in turn, minimizes the space on substrate 320 occupied by the solder balls or other conductive elements 302.

A package according to yet another embodiment of the invention (FIG. 8) includes a substrate 420 with top vias 426 extending into the substrate from the top surface 422 of the substrate. These features may be similar to the features discussed above with reference to FIGS. 1-3. Here again, a chip 440 or other microelectronic element is mounted to the substrate using solder elements 448. Substrate 420, however, has terminals 434 exposed at its top surface and connected to the circumferential walls 430 of the vias by traces 436. Thus, the package including the substrate 420 and microelectronic element 440 may be mounted to a circuit panel 452 with the top surface 422 of the substrate facing toward the circuit panel and hence with the chip 440 positioned between the substrate and the circuit panel. Terminals 434 can be connected to contact pads 450 on the circuit panel as, for example, by solder balls 454 or other conductive elements. In this arrangement, the mounted height H_{M} of the package is still further reduced. Also, in this arrangement, the ability to position the chip or other microelectronic element 440 close to the top surface 442 of the substrate minimizes the required height of solder balls or other conductive elements 454 used to connect the substrate with the circuit panel. Here again, the ability to use relatively small-diameter solder balls 454 minimizes the space occupied by the solder balls on the substrate and the area occupied by the assembly on the circuit panel. In a further variant, additional conductive elements may be provided on the bottom surface 424 of the substrate (the surface facing upwardly in FIG. 8) for mounting one or more further microelectronic elements to the bottom surface.

A package according to yet another embodiment of the invention includes a substrate 520 and chip 540 similar to the corresponding elements discussed above with reference to FIGS. 1-3. In this embodiment, however, a seal 502 is provided adjacent the periphery of the substrate and chip. As discussed in greater detail in the aforementioned co-pending applications, such a seal may be provided by a ring of an adhesive material or, more preferably, by a ring of solder or other metallic bonding material. Such a seal may be formed, for example, by providing metallic features wettable by solder around the periphery of the substrate top surface 522 and around the periphery of the chip front surface 542, and introducing molten solder between these features. This process may be performed concurrently with reflow of the solder to form modified solder elements 548. Such a seal can be used, for example, where chip 540 incorporates features such as a radiation-sensitive element, a surface acoustic wave element or a microelectromechanical structure exposed at its front surface 542. As discussed in greater detail in the aforementioned co-pending applications, the substrate 520 serves as a lid or cover for the chip and also serves as a mounting substrate.

Numerous variations and combinations of the features discussed above can be utilized. For example, in each of the embodiments discussed above, the solder elements are solid masses of a uniform solder composition. However, the solder elements may incorporate a core formed from a relatively high-melting metal such as copper, or from a non-metallic material such as glass, desirably coated with a metal wettable by the solder. The core remains in place within the solder element during the reflow process. Depending upon the diameter of the core, the core may or may not contact the contacts of the microelectronic elements, the circumferential walls of the vias or both. Also, the term “solder” as used herein should be understood broadly as including essentially any metallic composition which can melt, flow and wet other metallic features.

In a unit having only top vias (such as the unit of FIGS. 1-3), two or more microelectronic elements can be mounted to the top surface using the top vias. The traces on the substrate can provide interconnections between the top vias associated with the various microelectronic elements and thus may connect the microelectronic elements with one another. In a further variant, the substrate may be provided with both top and bottom vias, and microelectronic elements such as chips may be mounted to both sides of the substrate. Such a double-sided unit may have terminals exposed at its top side, its bottom side or both for mounting to a circuit panel or for mounting in a stacked arrangement similar to that shown in FIG. 7. In such a unit, the traces on the substrate typically would connect at least some of the top vias with at least some of the bottom vias so as to interconnect the microelectronic elements with one another.

Some or all of the operations discussed above used to form the various packages can be conducted while the substrate, the chip or both are in the form of a larger element such as a sheet or wafer incorporating numerous chips or substrates. The larger elements may be severed after assembly to provide individual units.

As these and other variations and combinations of the features discussed above can be utilized without departing from the present invention, the foregoing description of the preferred embodiments should be taken by way of illustration rather than by way of limitation of the invention as defined by the claims.

1. A microelectronic assembly including:
(a) a first microelectronic element having a front face with contacts thereon;
(b) a substrate having oppositely-directed top and bottom faces, and top vias extending downwardly into the substrate from said top face, said top vias having metallic circumferential top via walls, said top vias being tapered so that the diameters of said top vias decrease progressively in the downward direction away from said top surface, said substrate having electrically conductive traces thereon, at least some of said traces being electrically connected to at least some of said top via walls; and
(c) solder elements disposed at least partially within said top vias, said solder elements being bonded to said contacts and said top via walls.

2. The assembly as claimed in claim 1 wherein said top vias extend through said substrate to said bottom face, whereby each said top via defines a top opening at said top face and a bottom opening at said bottom face, said bottom opening being smaller than said top opening.

3. The assembly as claimed in claim 2 wherein at least some of said traces are disposed on said bottom face of said substrate.

4. The assembly as claimed in 1 wherein said first microelectronic element is a chip.

5. The assembly as claimed in claim 4 wherein said substrate has electrically conductive terminals exposed at said bottom surface and electrically connected to said top via walls.

6. The assembly as claimed in claim 5 wherein said terminals include bottom vias extending into said substrate from said bottom surface, said bottom vias having metallic circumferential bottom via walls, said bottom vias being tapered so that the diameters of said bottom vias decrease progressively in the upward direction away from said bottom surface.

7. The assembly as claimed in 6 further comprising bottom solder masses bonded to said bottom via walls and projecting downwardly from said bottom surface.

8. The assembly as claimed in 5 wherein said substrate forms a chip-scale package substrate for said chip.

9. The assembly as claimed in 1 wherein each said solder element is a unitary mass of solder.

10. The assembly as claimed in 1 wherein each said solder element includes a core and a layer of solder surrounding said core, said layer of solder being bonded to said top via walls and said contacts of said first microelectronic element.

11. The assembly as claimed in claim 10 wherein each said core is substantially spherical.

12. The assembly as claimed in claim 1 wherein said substrate includes a dielectric structure defining said top and bottom faces and a metallic coating on said substrate defining said top via walls.

13. The assembly as claimed in claim 12 wherein said dielectric structure is formed from a glass.

14. The assembly as claimed in claim 1 wherein said substrate is substantially CTE-matched with said first microelectronic element.

15. The assembly as claimed in 1 wherein said front surface of said first microelectronic element and said top surface of said substrate define a spacing height therebetween, and wherein said spacing height is less than the diameters of said vias at said top surface.

16. The assembly as claimed in 1 wherein said front surface of said first microelectronic element abuts said top surface of said substrate.

17. A method of making a microelectronic assembly comprising the steps of:
(a) juxtaposing a first microelectronic element with a substrate so that a front surface of the first microelectronic element confronts a top surface of the substrate, and so that solder elements partially received in top vias of the substrate are engaged with contacts exposed at the front surface of the microelectronic element and with metallic circumferential walls of said top vias, said vias being tapered so that a circumferential wall of each via slopes inwardly toward a central axis in the downward direction, away from said top surface; and
(b) reflowing said solder elements.; and
(c) solidifying said solder elements.

18. The method as claimed in claim 17 further comprising moving said first microelectronic element toward said substrate during said reflowing step.

19. The method as claimed in claim 18 wherein said moving step includes at least partially impelling movement of said first microelectronic element toward said substrate by interfacial tension of molten solder with said metallic circumferential walls of said vias during said reflowing step.

20. The method as claimed in claim 17 wherein said contacts of said first microelectronic element bear at least some of said solder elements prior to said juxtaposing step, said juxtaposing step including aligning said first microelectronic element with said substrate so that solder elements on said contacts fit into said vias.
